(19) United States
(12) Patent Application Publication
(10) Pub. No.: US 2006/0256889 A1
(43) Pub. Date: Nov. 16, 2006

(54) Demodulation method and demodulation circuit

(75) Inventor: Shigeru Amano, Tokyo (JP)

Correspondence Address: NIXON PEABODY, LLP, 401 9TH STREET, NW, SUITE 900, WASHINGTON, DC, 20004-2128, US

(73) Assignee: OKI ELECTRIC INDUSTRY CO., LTD., Tokyo (JP)

(21) Appl. No.: 11/359,478

(22) Filed: Feb. 23, 2006

(30) Foreign Application Priority Data
May 16, 2005 (JP) 2005-142982

(51) Int. Cl. H03K 7/06; H04L 27/14

(52) U.S. Cl. 375/271; 375/334

(57) ABSTRACT

A modulation method includes modulating a sending data, calculating a current modulation data of the modulated sending data in synchronization with a clock signal and demodulating the modulated sending data by comparing the calculated current modulation data and a modulation data calculated by the clock signal at prior one symbol.

### BACKGROUND OF THE INVENTION

1. Field of the Invention

The present invention relates to a simplified demodulation method and circuit, being included in a modulation circuit to generate a frequency shift keying (hereinafter referred to as ‘FSK’) modulation signal or a phase shift keying (hereinafter referred to as ‘PSK’) modulation signal, and demodulates a modulation data to test the modulation circuit therein, etc., without transformation of the signal in time domain (analog signal converted from digital signal) or transformation of the signal in frequency domain, for example, in order to test a large scale integration circuits (hereinafter referred to as ‘LSI’).

2. Description of the Related Art

Conventionally, the technologies relating to FSK modulation circuit or FSK demodulation circuit are described as in the following paten document.

Patent Document 1: Japanese Patent Laid-Open No. H9-322144. (FIG. 1, FIG. 2)

In the patent document 1, there is a description of the technology of the equipment for transmitting encrypted voice signal of TV, which enables only the subscribers to listen to the encrypted voice and disables non-subscribers to listen to the encrypted voice, in a TV signal sending and receiving system (for example, a cable TV (CATV) system). The FSK modulation circuit and the FSK demodulation circuit are included in the above equipment for transmitting encrypted voice signal of TV. AT the same time, in the patent document 1, there is no description of a circuit configuration of the FSK modulation circuit or the FSK demodulation circuit.

In FIG. 11 is a circuit diagram showing an example of the conventional tow-digit FSL modulation circuit. The FSK modulation circuit has the configuration, as follows. First, n (n: an arbitrary positive integer) bits of the I channel (hereinafter referred to as ‘I-CH’) modulation signal S1 is generated from the sending data TXD by the I-CH demodulation signal generator, and at the same time, n bits of the Q channel (hereinafter referred to as ‘Q-CH’) modulation signal S2 is generated from the sending data TXD by the Q-CH modulation signal generator 2. The I-CH modulation signal S1 is also converted to the analog signal S3 by the I-CH digitaI-analog (hereinafter referred to as ‘A/D’) converter 3, and at the same time, the Q-CH modulation signal S2 is converted to the analog signal S4 by the Q-CH D/A converter 4. After the high-frequency component of the analog signal S3 is eliminated by the low-pass filter for eliminating noise (hereinafter referred to as ‘LPF’) 5; and the high-frequency component of the analog signal S4 is also eliminated by the LPF 6, the output signal S5 from the LPF 5 and the output signal S6 from the LPF 6 are quadrature modulated by the quadrature modulator 7, and then the modulated signal thereof is amplified by the power amplifier (hereinafter referred to as ‘Power AMP’) 8 to output the FSK modulation signal FMS.

Conventionally, when the modulation operation of the above-mentioned FSK modulation circuit is tested, signals on the output sides of the D/A converter 3, 4 are transformed to time domain or frequency domain, and then it is checked if the signals thereof are modulated correctly in frequency domain. For example, when the checking is done in time domain, the output signal S5, S6 of the LPF 5,6 are observed with an oscilloscope by the eye pattern, under the test condition that the sending data is fixed to logic value 0 or 1, or the sending data is changed to logic level 1 or 0, to determine if the correct modulation is done or not, through a time consuming observation. Further, when the checking is done in frequency domain, it is checked if the frequency deviation is correct or not, under the test condition that the sending data is fixed to logic value 0 or 1, or the sending data is changed to logic level 1 or 0, inputting the FSK-modulation signal of the FSK-modulation-signal FMS into a spectrum analyzer, etc.

### SUMMARY OF THE INVENTION

However, in the conventional test method to check the modulation operation of the FSK-modulation circuit, the signal under the test is needed to go through not only the I-CH modulation signal generator 1 and the Q-CH modulation signal generator 2, but also the LPF 5,6 for elimination of noise, the guadrature modulator 7, and so on. Consequently, the conventional test method can not be simple. Furthermore, when the operation of the I-CH modulation signal generator 1 and the Q-CH modulation generator 2 is checked for a LSI testing, the conventional test includes the other factors such as analog factor, etc. Consequently, the conventional test method can not be optimum.

To solve the before mentioned problems, checking of the operation is possible by demodulating the I-CH modulation signal S1 from the I-CH modulation signal generator 1 and the Q-CH modulation signal S2 from the Q-CH modulation signal generator 2, for example, installing the FSK demodulation circuit described in the patent document 1 into the FSK modulation circuit of FIG. 11. However, as the configuration of the FSK demodulation circuit is complex and the circuit scale of the FSK demodulation circuit is large, when the FSK demodulation circuit is installed into the FSK modulation circuit, the circuit scale of the whole FSK modulation circuit with the FSK demodulation circuit is not only large but also high cost. Consequently, the above method can not be optimum.

The object of the present invention is to solve the above mentioned problems and to provide a simplified demodulation method and circuit having a function of demodulating digital data such as I-CH modulation signal and Q-CH modulation signal before D/A conversion.

A demodulation circuit according to the present invention inputs a plurality of bits of I-CH modulation signal and a plurality of bits of Q-CH modulation signal generated from the sending data; and the demodulation circuit calculates in advance the value of said I-CH and said Q-CH when said sending data at one symbol after has the same data as at one symbol before, then said demodulation circuit conducts demodulation, being comparing said calculated value with said plurality of bits of I-CH modulation signal and a plurality of bits of Q-CH modulation signal.

Another demodulation circuit according to the present invention inputs a most significant sign bit in a plurality of bits of I-CH modulation signal generated from the sending data; and a most significant sign bit in a plurality of bits of Q-CH modulation generated from the sending data, subsequently another demodulation circuit according to the present invention carries out the modulation, only comparing a most significant sign bit in a plurality of bits of I-CH modulation signal at one symbol after; with a most significant sign bit in a plurality of bits of Q-CH modulation at one symbol after, when the ratio between the transmission speed of said sending data and the frequency deviation is 2:1.

In the demodulation method according to the present invention, said modulated sending data is demodulated by modulating the sending data, calculating the current modulation data of said demodulated sending data, and comparing said calculated current modulation data with said calculated sending data at one symbol before by the clock signal.

By the demodulation circuit according to the present invention, a simplified demodulation data can be acquired from digital signals of I-CH modulation signal and Q-C modulation signal.

By another demodulation circuits according to the present invention, simplified demodulation can be conducted without deciding the constellation location in case where the sending data at one symbol after continues to have the same data (same phase) as at one symbol before, additionally by using small bit number no more than one bit.

In the demodulation method according to the present invention, as the demodulation of the modulated sending data is carried out by comparing the current modulation data with the calculated modulation data at one symbol before, an simplified demodulation can be conducted easily.

### BRIEF DESCRIPTION OF THE DRAWINGS

FIG. 1 is a circuit diagram of a two-digit FSK modulation circuit with a simplified FSK demodulation circuit according to the first embodiment.

FIG. 2 is a timing chart of the I-CH side operation in the FSK demodulation circuit 30 of FIG. 1.

FIG. 3 is a circuit diagram of a two-digit FSK modulation circuit with other simplified FSK demodulation circuit according to the first embodiment.

FIG. 4 is a circuit diagram of a two-digit FSK modulation circuit with a simplified FSK demodulation circuit according to the second embodiment.

FIG. 5 is a timing chart of the I-CH side operation in the FSK demodulation circuit 30A of FIG. 4.

FIG. 6 is an explanatory diagram of FIG. 4.

FIG. 7 is a circuit diagram of a two-digit FSK modulation circuit with other simplified FSK demodulation circuit according to the second embodiment.

FIG. 8 is a circuit diagram of a two-digit PSK modulation circuit with other simplified PSK demodulation circuit according to the third embodiment.

FIG. 9 is a timing chart of the I-CH side operation in the PSK demodulation circuit 30B of FIG. 8.

FIG. 10 is a circuit diagram of a two-digit PSK modulation circuit with other simplified PSK demodulation circuit according to the third embodiment.

FIG. 11 is a circuit diagram of an example of the conventional tow-digit FSK modulation circuit.

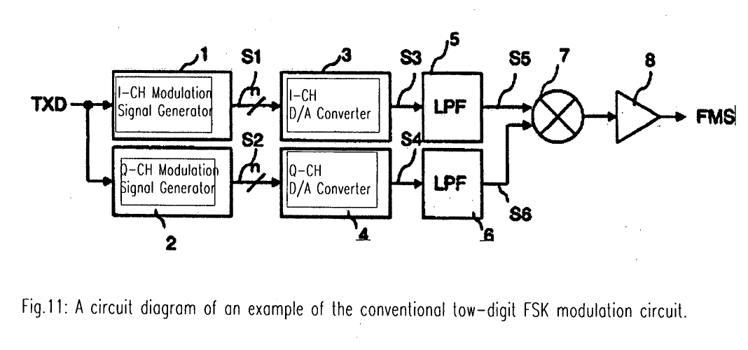

### DETAILED DESCRIPTION OF THE PREFERRED EMBODIMENTS

A demodulation circuit according to the preferred embodiment consists of a calculation circuit inputting a plurality of bits of I-CH modulation signal and Q-CH modulation signal generated from a sending data and calculating the modulation data at one symbol after without changing the phase thereof; a delay device delaying said modulation data at one symbol after by one symbol period; and a comparator comparing said plurality of bits of I-CH modulation signal and Q-CH modulation signal with said delayed data and outputting the modulation signal.

### First Embodiment

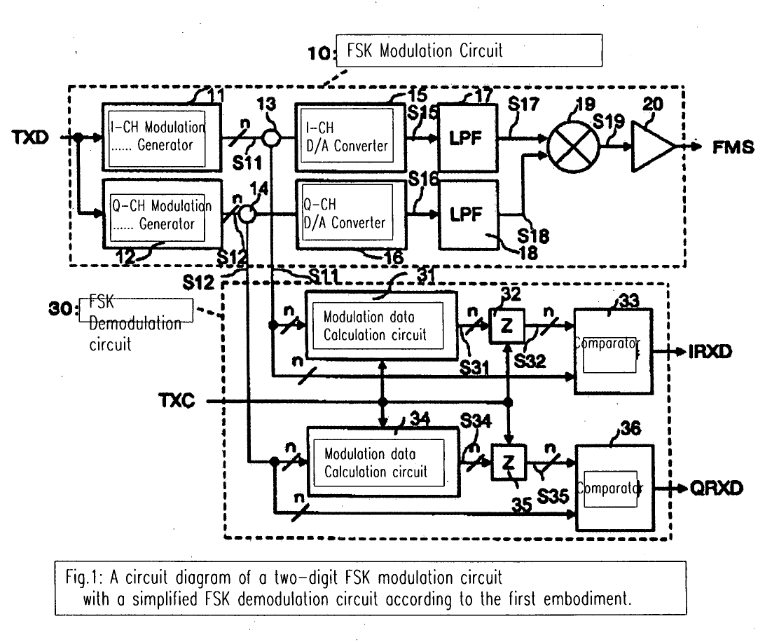

FIG. 1 is a circuit diagram of a two-digit FSK modulation circuit with a simplified FSK modulation circuit according to the first embodiment of the invention.

The two-digit FSK modulation circuit 10 includes a I-CH modulation signal generator 11 generating a n bits (n: arbitrary positive integer) of I-CH modulation signal S11 from a sending data TXD; and a Q-CH modulation signal generator 12 generating the n bits of Q-CH modulation signal S2 from the sending data TXD, with an I-CH D/A converter 15 and a Q-CH D/A converter 16 connected respectively to the output sides thereof through a selecting device 13, 14. An I-CH side selecting device 13 has a function of selecting a destination of the n bits of I-CH modulation signal S11 and providing the I-CH D/A converter 15 or a simplified FSK demodulation circuit 30 with said signal, and consists of a selector, etc. A Q-CH side selecting device 14 has a function of selecting a destination of the n bits of I-CH modulation signal S11 and providing the Q-CH D/A converter 16 or a simplified FSK demodulation circuit 30 with said signal, and consists of the selector, etc.

The I-CH D/A converter 15 is a circuit converting the I-CH modulation signal S11 inputted through the selecting device 13 to the analog signal S15; with a LPF 17 for eliminating noise connected to the output side thereof. The Q-CH D/A converter 15 is a circuit converting the Q-CH modulation signal S12 inputted through the selecting device 14 to an analog signal S16; with a LPF 18 for eliminating noise connected in the output side thereof. The LPF 17 is a circuit outputting an output signal S17; with a quadrature modulator 19 connected to the output side thereof. The LPF 18 is a circuit eliminating the high-frequency component of an analog signal S16; and outputting an output signal S18; with the quadrature modulator 19 connected to the output side thereof. The quadrature modulator 19 is a circuit quadrature modulating an output signal 17 and an output signal S18; with a power amplifier (hereinafter referred to as power AMP) 20 connected to the output side thereof. The power AMP 20 amplifies an output signal 19 of the quadrature modulator 19 and outputs a two-digit FSK modulation signal FSK.

An simplified FSK modulation circuit 30 is a circuit not operating during the normal operation (ie. during modulation circuit operation) ;and operating during the LSI test of the operation through the output from the modulation circuit, and an simplified FSK modulation circuit 30 includes a modulation calculation circuit 31,34 connected respectively to each selecting device 13,14. An I-CH side modulation data calculation circuit 31 is a circuit calculating the n bits of an modulation data S31 at one symbol after without changing the phase of the n bits of an I-CH modulation signal S11 inputted through the selecting device 13 based on a sending clock TXC responding to the sending data TXD, and An I-CH side modulation circuit 30 consists of a calculation circuit, etc, with an comparator connected 33 in the output side thereof through an one-symbol delaying device 32. The one-symbol delaying device 32 is a device outputting the n bits of modulation data S31 delayed by one symbol based on the sending clock, and consists of a flip-flop circuit (hereinafter referred to as ‘FF’) etc. The comparator 33 is a circuit comparing the n bits of the modulation data S32 with the n bits of I-CH modulation signal S11 ;and outputting a simplified FSK demodulation data IRXD based on the comparing results thereof, and consists of a logic gates, etc.

The Q-CH side modulation data calculation circuit 34 is a similar circuit to the I-CH side modulation calculation circuit 31, calculating n bits of the modulation data S34 at one symbol after without changing the phase of b bits of the Q-CH modulation signal S12 being inputted through the selecting device 14, based on the sending clock TXC, and the Q-CH side modulation data calculation circuit 34 consists of a calculation circuit, etc., with the selector 36 connected to the output side thereof through the one symbol delay device 35. The one symbol delay device 35 is a device delaying n bits of the modulation data S34Q-CH modulation signal S12 by one symbol, based on the sending clock TXC; and outputting no bits of the modulation data S35, and the one symbol delay device consists of FF, etc. The comparator 36 is a circuit comparing n bits of the modulation data S35 with n bits of the Q-CH modulation signal S12; and outputting a simplified modulation data QRXD from the comparing results thereof, and consists of a logic gate, etc.

When the D/A converters 15 and 16 sides are selected by the selecting devices 13 and 14, the output sides of the I-CH demodulation signal generator 11 and the Q-CH modulation signal generator 12 are connected to the D/A converter 15, 16, and the FSK modulation circuit 10 operates as follows.

The inputted sending data TXD is generated n bits of the I-CH modulation signal S11 as described the following formula (1), by the I-CH modulation signal generator 11, and at the same time the sending data TXD is generated n bits of the Q-CH modulation signal S12 as described the following formula (2), by the I-CH modulation signal generator 11.

N bits of the I-CH modulation signal S11 - - - formula (1):
when sign=1; S1i(t)=Re(cos(2*π*(f1)*t))
when sign=0; S0i(t)=Re(cos(2*π*(f0)*t))

N bits of the Q-CH modulation signal S12 - - - formula (2):
when sign=1; S1q(t)=Imag(cos(2*π*(f1)*t))
when sign=0; S0q(t)=Imag(cos(2*π*(f0)*t))

The generated n bits of I-CH modulation signal S11 and the generated n bits of Q-CH modulation signal S12 are sent to the D/A converter 15, 16 through the selecting device 13, 14, respectively. The I-CH modulation signal S11 is converted to the analog signal S15 by the I-CH D/A converter 15 and the high frequency component of the analog signal S16 is eliminated by the LPF 18. The Q-CH modulation signal S12 is converted to the analog signal S16 by the Q-CH D/A converter 16 and the high frequency component of the analog signal S16 is eliminated by the LPF 18. The output signal S17 from the LPF 17 and the output signal S18 from the LPF 18 are quadrature modulated (i.e. multiplied), subsequently the output signal S19 outputs, as described by the following formula.

Output signal S19 - - - formula (3):
when sign=1; S1(t)=cos(2*π*(f1)*t)
when sign=0; S0(t)=cos(2*π*(f0)*t)

The output signal S19 outputs is amplified by the power AMP 20 and is outputted as a two digit FSK modulation signal FMS.

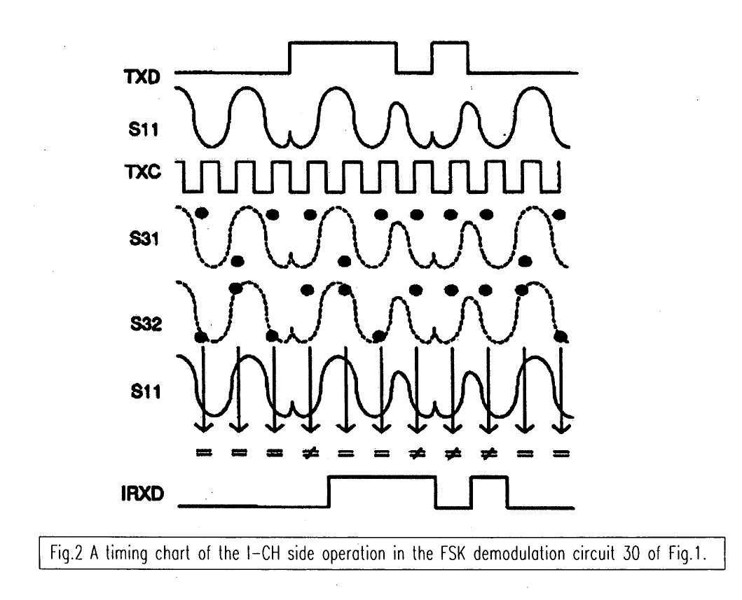

FIG. 2 is a timing chart describing the I-CH side operation of the FSK demodulation circuit 30 in FIG. 1.

When the side of FSK demodulation circuit 30 is selected by the selecting devices 13 and 14, the output side of the I-CH modulation generator 11 and the Q-CH modulation generator 12 are connected to the FSK demodulation circuit 30, then the FSK demodulation circuit 30 operates as below.

When the n bits of I-CH modulation signal S11, the sending data TXD modulated by the I-CH modulation signal generator 11, is sent to the I-CH side of the FSK modulation circuit 30 through the selecting device 13, the modulation data calculation circuit 31 calculates the n bits of I-CH signal S11 being reached thereto in case where the same sending data TXD (phase) after one symbol continues to be given, at every sending clock timing TXC, and outputs the n bits of modulation data S31. The modulation data S31 thereof is the modulation data in case where the sending data TXD has the same value as the sending data at one symbol before.

The modulation data S31 is delayed by the delaying device 32 by one symbol and the one symbol delayed modulation data S31 thereof is inputted to the comparator 33. The comparator 33 compares the one symbol delayed modulation signal S32 with the current modulation signal S11. In case of where the two signals thereof are matched, it is decided that there is no change in the sending data TXD (pahse) and then the demodulation result of the FSK demodulation data IRXD having the same sign as before symbol is outputted. In contrast, in case where the two signals thereof are not matched, it is decided that there is a change in the sending data TXD (phase) and then the demodulation result of the FSK demodulation data IRXD having the reversed sign (i.e. 0/1 is reversed) is outputted.

Further, when the n bits of Q-CH modulation signal S12, the sending data TXD modulated by the Q-CH modulation generator 12, is sent to the Q-CH side of the FSK modulation circuit 30 through selecting device 14, the mostly similar operations are done by the modulation data calculation circuit 34, one symbol delaying device, and the comparator 36, and then the simplified FSK demodulation data QRXD is outputted.

As explained before, the I-CH modulation signal S11 and the Q-CH modulation signal S12 generated by the I-CH modulation signal generator 11 and the Q-CH modulation signal generator 12 are inputted to the D/A converter 15, 16, respectively, at the FSK modulation circuit side 10, and are sent as the FSK modulation signal MS through the quadrature modulator 19 and the analog component of power AMP 20. In contrast, since the FSK demodulation circuit is a test circuit and the I-CH modulation signal S11 or the Q-CH modulation signal S12 is not through the analog component, etc., no noise components exist therein. For the above reason, in case where the same sending data TXD is set as at one symbol after at a certain time t1, the modulation signal value of the I-CH/Q-CH can be calculated correctly. Consequently, it is decided that when the sending data TXD is matched to the calculated value thereof, the sending data TXD is not changed and when the sending data TXD is not matched to the calculated value thereof, the sign 0/1 of the sending data TXD is changed.

According to the first embodiment, as the simplified FSK demodulation circuit 30 is built in the FSK modulation circuit 10, the simplified FSK demodulation data IRXD,QRXD can be acquired from the I-CH modulation signal S11 and the Q-CH modulation signal S12 of digital signals by the above FSK demodulation circuit 30. In the above operations, there is the precondition 1,2 as follows.

Precondition 1: there is no noise component in the data.

Precondition 2: In the LSI, the simplified demodulation is conducted by the same clock as the digital I-CH demodulation signal generator 11 and the digital Q-CH demodulation signal generator 12.

Since the above preconditions are valid according to the first embodiment of the present invention, the constellation location of the case where the same sending data TXD (phase) continues at one symbol after can be detected. The comparator 33,36 checks whether the above constellation is matched to the thereof. Consequently, only addition of such simplified circuits as the modulation data calculation circuit 31,34, the one symbol delaying device 32,35, and comparator 33,36 to the FSK modulation circuit 10 can realize the verify operation thereof without analog components beyond the D/A converter 15, 16 at the FSK modulation circuit side.

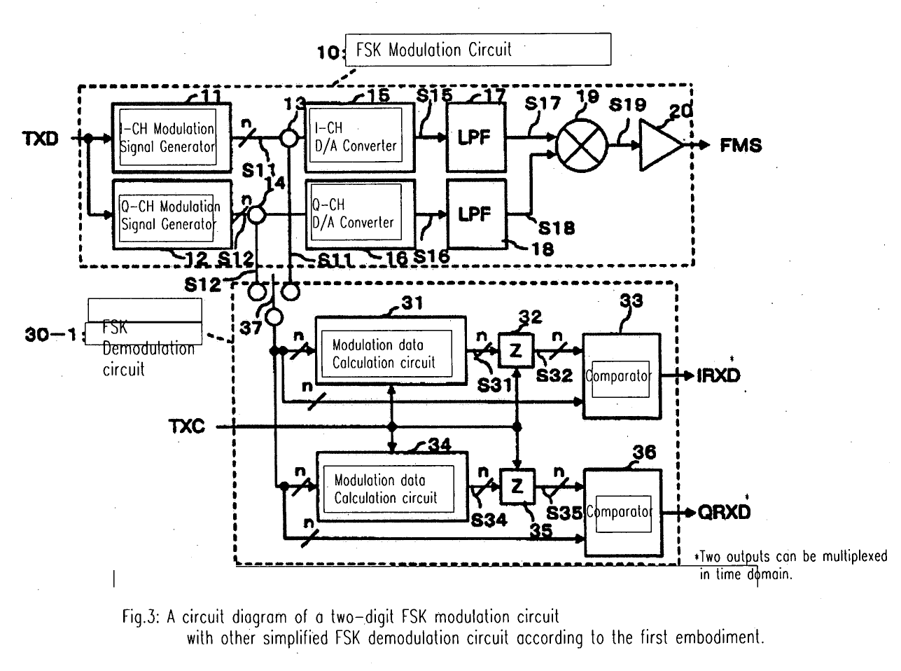

FIG. 3 is a view of a circuit diagram of two-digit FSK modulation circuit with other simplified FSK demodulation circuit according to the first embodiment.

The FSK modulation circuit 30 is configured to connect one of the I-CH side and the Q-CH side of the FSK demodulation circuit 30 selected by the selecting device 13, 14 by a switching device 37. The switching device 37 consists of switching elements switched by the control signal, etc. Even when the above switching device is added, the mostly same effect as in FIG. 1 can be acquired.

### Second Embodiment

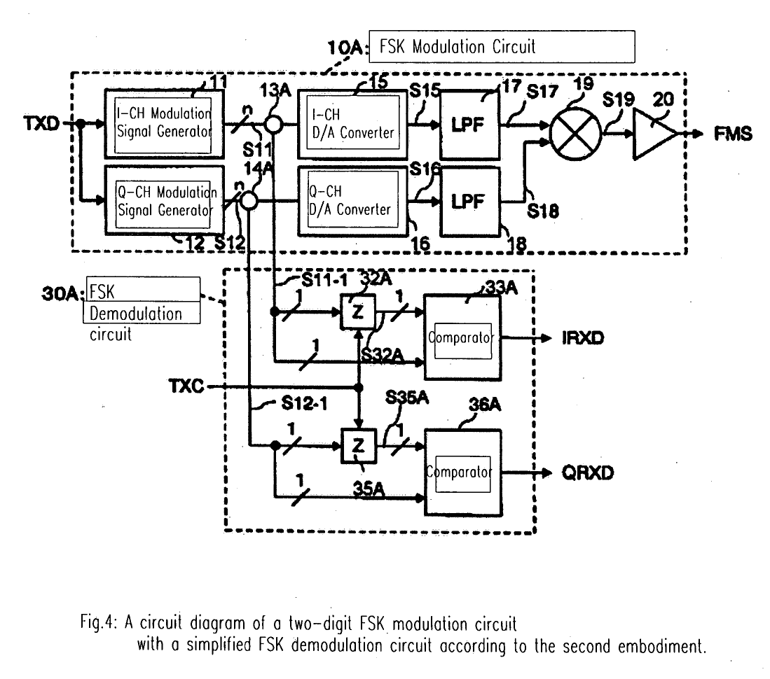

FIG. 4 is a circuit diagram of the two-digit FSK modulation circuit including a simplified FSK demodulation circuit according to the second embodiment. The component identical to the component in FIG. 1 is given the same numerals as in FIG. 1.

According to the second embodiment, the FSK demodulation circuit 30 is further simplified taking advantage of the fact that simplification can be done when the condition 1 described as below is valid.

Condition 1: When the ration of the transmitting speed (the sending data TXD speed) and the frequency deviation is 2:1.

When the above condition is valid, in case where the same sending data TXD continues after one symbol, the constellation never fails to be at the location rotated by 180 degrees, and in case where the sending data turns to the different data (0/1), the constellation returns back to the original location.

Based on the above principal, the second embodiment includes a FSK modulation circuit 10A having a different configuration from the FSK modulation circuit 10 according to the first embodiment, and connects a simplified FSK modulation circuit 30A having a different configuration from the FSK demodulation circuit 10 according to the first embodiment to the above FSK modulation circuit 10A.

In the modulation circuit 10A, the only one different point is that a selecting device 13A, 14A is built-in instead of the selecting device 13, 14. The I-CH side selecting device 13A has a function of inputting the n bits of I-CH modulation signal S11 from the I-CH signal generator 11 to the I-CH D/A converter 15 by the switching operation directed by the control signal, etc., or inputting the most significant one bit (S11-1) in the n bits of I-CH signal thereof to the simplified FSK demodulation circuit 30A, and consists of a selector, etc. The Q-CH side selecting device 14A has a function of inputting the n bits of Q-CH modulation signal S12 from the Q-CH signal generator 12 to the Q-CH D/A converter 16 by the switching operation directed by the control signal, etc., or inputting the most significant one bit (S12-1) in the n bits of Q-CH signal thereof to the simplified FSK demodulation circuit 30A, and consists of a selector, etc.

An simplified FSK modulation circuit 30A is a circuit not operating during the normal operation (ie. during modulation circuit operation); and operating during the LSI test of the operation through the output from the modulation circuit, and an simplified FSK modulation circuit 30 includes a one symbol delaying device 32A,35A connected respectively to each selecting device 13A, 14A with a comparator 33A,36A connected to the output side, respectively. The I-CH one symbol delaying device 32A is a circuit delaying the most significant one bit of modulation signal S11-1 by one symbol based on the sending clock TXC; and outputting the most significant one bit of modulation data S32A, and the I-CH one symbol delaying device 32A consists of FF, etc. The comparator 33A is a circuit comparing the most significant one bit of modulation data S32A with the most significant one bit of I-CH modulation signal S11-1; outputting the simplified FSK demodulation data IRXD from the comparing results thereof, and the comparator 32A consists of logic gate, etc.

The Q-CH one symbol delaying device 35A is a circuit delaying the most significant one bit of Q-CH modulation signal S12-1 by one symbol based on the sending clock TXC; and outputting the most significant one bit of modulation data S35A, and the Q-CH one symbol delaying device 35A consists of FF, etc. The comparator 36A is a circuit comparing the most significant one bit of modulation data S35A with the most significant one bit of Q-CH modulation signal S12-1; outputting the simplified FSK demodulation data QRXD based on the comparing results thereof, and the comparator 35A consists of logic gate, etc. When the D/A converter 15,16 is selected by the selecting 13A, 14A, the output sides of the I-CH modulation signal generator 11 and the Q-CH modulation signal generator 12 to the D/A converter 15, 16 and the FSL modulation circuit 10A operates modulation similarly to the first embodiment.

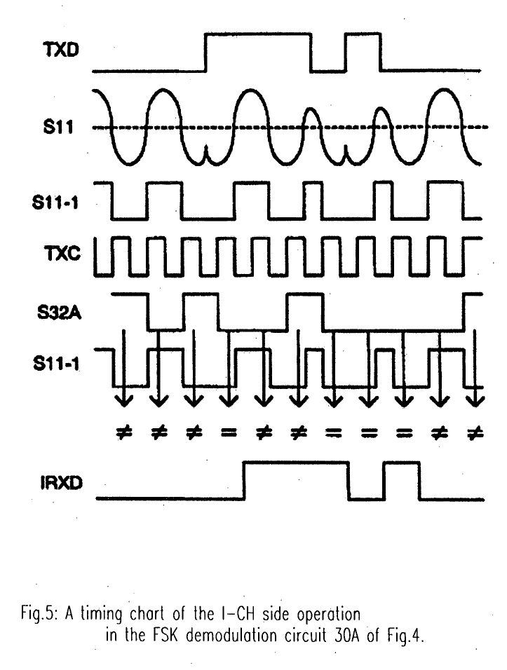

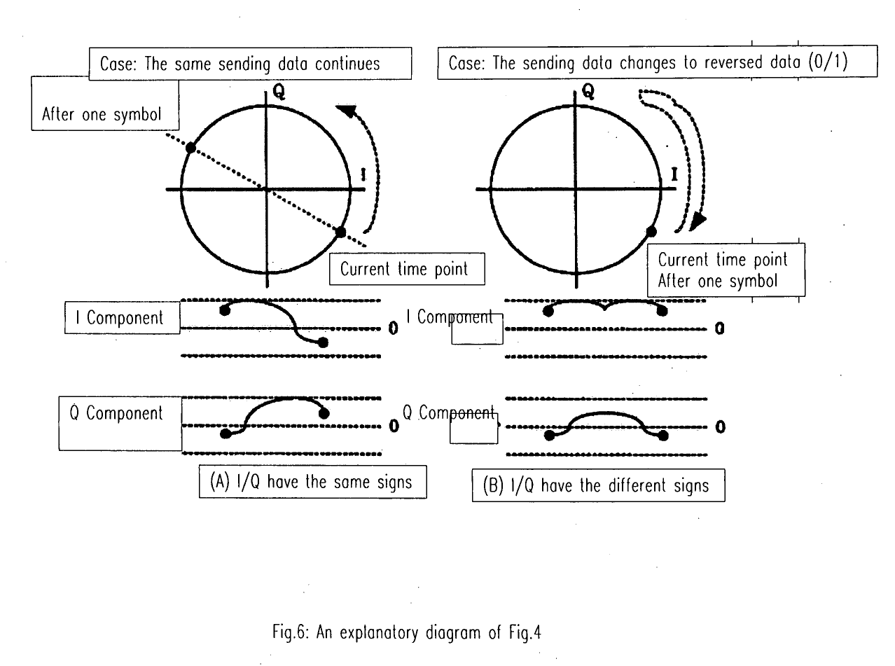

FIG. 5 is a timing chart describing an I-CH side operation of the FSK demodulation circuit 30A in FIG. 4. Furthermore, FIG. 6(A),(B) is an explanatory diagram of the operation in FIG. 4. The line (A) of FIG. 6 is the diagram describing the case where the I/Q has the different sign, and the line (B) of FIG. 6 is the diagram describing the case where the I/Q has the same sign.

When the FSK demodulation circuit 30A is selected by the selecting device 13A, 14A, the most significant one bit of I-CH modulation signal S11-1 representing the sign information of the n bits of I-Ch modulation signal S11 from the I-CH modulation signal generator 11; and the most significant one bit of Q-CH modulation signal S12-1 representing the sign information of the n bits of Q-Ch modulation signal S12 from the I-CH modulation signal generator 12 are provided the FSK demodulation circuit 30A, as described by the following formula(4),(5).

The most significant one bit of I-CH modulation signal S11-1 - - - (4):
Si(t)=Re(cos(2*π*(fc)*t+φ(t)))

The most significant one bit of Q-CH modulation signal S12-1 - - - (5):
Sq(t)=Imag(cos(2*π*(fc)*t+φ(t)))

In the FSK demodulation circuit 30A, the most significant one bit I-CH demodulation signal S11-1 is delayed by one symbol by I-CH side one symbol delaying device 32A, and the delayed most significant one bit of modulation signal 32A is inputted to the comparator 33A.

The comparator 33A compares the one symbol delayed most significant one bit of modulation S32A with the most significant one bit of I-CH modulation signal S-11-1. In case of where the two signals thereof are not matched, it is decided that there is no change in the sending data TXD (phase) and then the demodulation result of the FSK demodulation data IRXD having the same sign as before is outputted. In contrast, in case where the two signals thereof are matched, it is decided that there is a change in the sending data TXD (phase) and then the demodulation result of the FSK demodulation data IRXD having the reversed sign (i.e. 0/1 is reversed) is outputted.

At the same time, the most significant one bit of Q-CH modulation signal S12-1 is delayed by one symbol by the Q-CH side one symbol delaying device 35A, as in the I-CH side, and is compared by the comparator 36A, then the FSK demodulation data QRXD is outputted.

According to the second embodiment, the modulation frequency Ø(t) is changed by 180 degrees as in FIG. 5(A) when the sending data is 1 (Ø1(t)), and is not changed as in FIG. 6(B) when the sending data is 0 (Ø0(t)). In other words, the second embodiment takes advantage of the state that the modulation frequency can be processed as changed by 180 degrees, or not, after the constellation location is decided, as two-digit PSK.

The second embodiment has the mostly same effect as the first embodiment. Furthermore, there is another effect as follows. As shown in FIG. 6, in the state of 180 degree change, the I-CH modulation signal S11 and the Q-CH modulation signal of FIG. 1 are processed as n-bit signals, while the decision can be made only by the one bit of I-CH modulation signal S11-1 and the one bit of Q-CH modulation signal S12-1, representing the sign of the most significant bit, according to the second embodiment. In other words, the reason is as follows. In case where the sign is reversed after one symbol, it can be decided that the sending data TXD continues the same sign, and in case of the same sign, it can be decided that the sending data TXD is changed. Consequently, simplified demodulation can be conducted without deciding the constellation location, additionally by using small bit number no more than one bit.

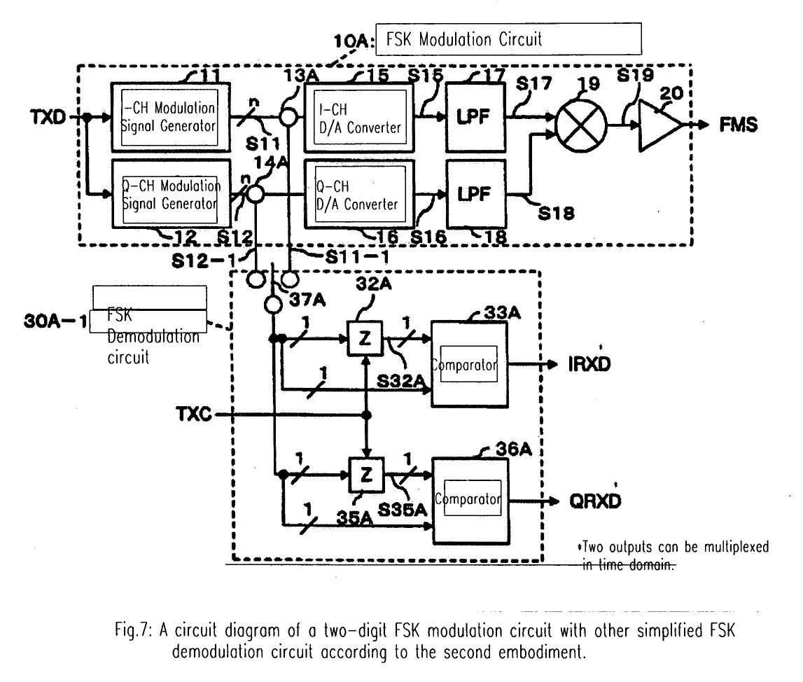

FIG. 7 is a view of a circuit diagram of two-digit FSK modulation circuit with other simplified FSK demodulation circuit according to the second embodiment. The component identical to the component in FIG. 4 is given the same numerals as in FIG. 4.

The FSK modulation circuit 30A-1 is configured to connect one of the I-CH side and the Q-CH side of the FSK demodulation circuit 30A-1 selected by the selecting device 13A, 14A by a switching device 37A. The switching device 37A consists of switching elements switched by the control signal, etc. Even when the above switching device 37A is added, the mostly same effect as in FIG. 4 can be acquired.

### Third Embodiment

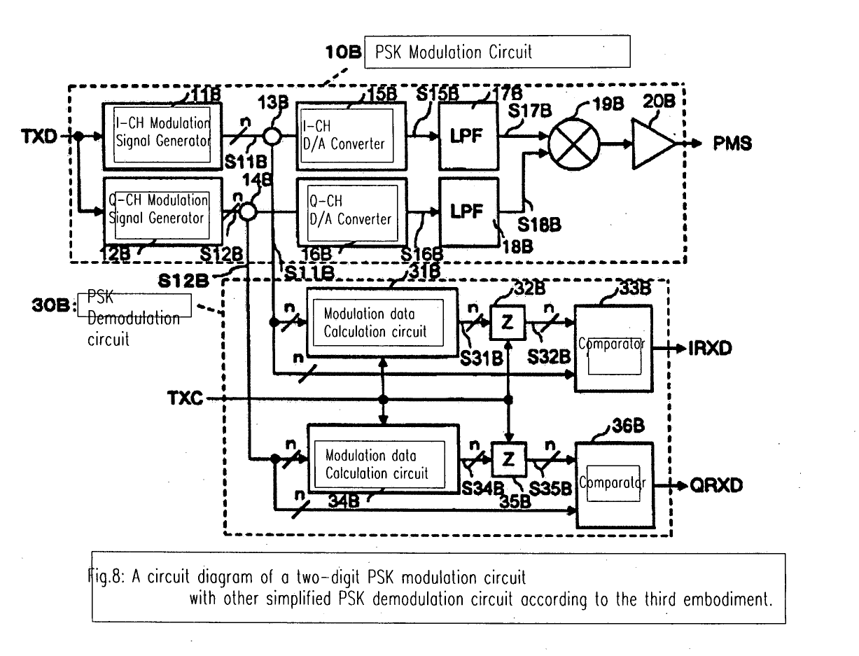

FIG. 8 is a circuit diagram of a two-digit FSK modulation circuit with a simplified FSK modulation circuit according to the third embodiment of the invention.

The two-digit FSK modulation circuit 10B includes a I-CH modulation signal generator 11B generating a n bits of I-CH modulation signal S11B from the sending data TXD; and a Q-CH modulation signal generator 12B generating the n bits of Q-CH modulation signal S2B from the sending data TXD, with an I-CH D/A converter 15B and a Q-CH D/A converter 16B connected respectively to the output sides thereof through a selecting device 13B, 14B, as the two-digit FSK modulation circuit 10 according to the first embodiment in FIG. 1. An I-CH D/A converter 15B is a circuit converting an I-CH modulation signal S11B inputted through the selecting device 13B to an analog signal S15B, with a LPF 17B connected to the output side thereof. An Q-CH D/A converter 16B is a circuit converting an Q-CH modulation signal S12B inputted through the selecting device 14B to an analog signal S16B, with a LPF 18B connected to the output side thereof.

The LPF 17B is a circuit eliminating the high frequency components out of the analog signal S15B; and outputting an output signal S17B; with a quadrature modulator 19B connected to the output side thereof. The LPF 18B is a circuit eliminating the high frequency components out of the analog signal S16B; and outputting an output signal S18B; with the quadrature modulator 19B connected to the output side thereof. The quadrature modulator 19B is a circuit quadrature modulating an output signal S17B and an output signal S18B; with a power amplifier (hereinafter referred to as Power AMP) 20B connected to the output side thereof. The Power AMP 20B amplifies an output signal S19B of the quadrature modulator 19B and outputs a two-digit PSK modulation signal PMS.

An simplified FSK modulation circuit 30B includes a modulation data calculation circuit 31B,34B connected to each selecting device 13B, 14B, respectively, as the FSK modulation circuit 30 according to the first embodiment in FIG. 1. The I-CH modulation data calculation circuit 31B is a circuit calculating n bits of I-CH modulation data S31B at one symbol after without changing the phase of the n bits of I-CH modulation signal S11B inputted through the selecting device 13B, based on the sending clock TXC responding to the sending data TXD, with a comparator 33B connected to the output side thereof through the one symbol delaying device 32B. The one symbol delaying device 32B is a device delaying the n bits of modulation S31B by one symbol based on the sending clock TXC; and outputting the n bits of modulation data S32B. The comparator 33B is a circuit comparing the n bits of modulation data S32B with the n bits of I-CH modulation signal S11B; outputting the simplified PSK demodulation data IRXD based on the comparing results thereof.

A Q-CH side modulation data calculation circuit 34B is a circuit calculating a modulation data 34B at one symbol after without changing the phase of the b nits of Q-CH modulation signal S12B inputted through the selecting device 14B based on the sending clock TXC, as the I-CH side modulation data calculation circuit 31B, with a comparator 36B connected to the output side thereof through a one symbol delaying device 35B. The one symbol delaying device 35B is a device delaying the n bits of modulation data S34B by one symbol based on the sending clock TXC; and outputting a n bits of modulation signal S35B.

The comparator 36B is a circuit comparing the n bits of modulation data S35B with the N bits of Q-CH modulation signal S12B; and outputting the simplified PSK demodulation data QRXD based on the comparing results thereof.

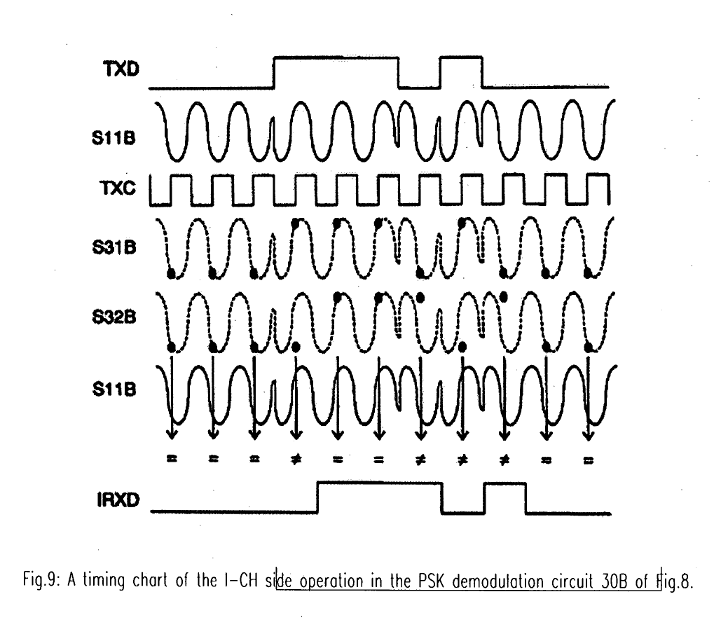

FIG. 9 is a timing chart describing the I-CH side operation of the PSK demodulation circuit 30B in FIG. 8.

The tow-digit PSK modulation circuit 10B and the simplified PSK demodulation circuit 30B according to the third embodiment conducts the mostly same operations as the tow-digit PSK modulation circuit 10 and the simplified PSK demodulation circuit 30 according to the first embodiment. The different point thereof is simply that when the sending data TXD is changed (0/1), the differential value between the original value and the changed value is not the same, however, the matching condition is the same. The reason thereof is as follows. When there is no matching, it is simply recognized that the sign of the sending data TXD is changed, then what is the value is not important. Consequently, the third embodiment has the mosly same effect as the first embodiment.

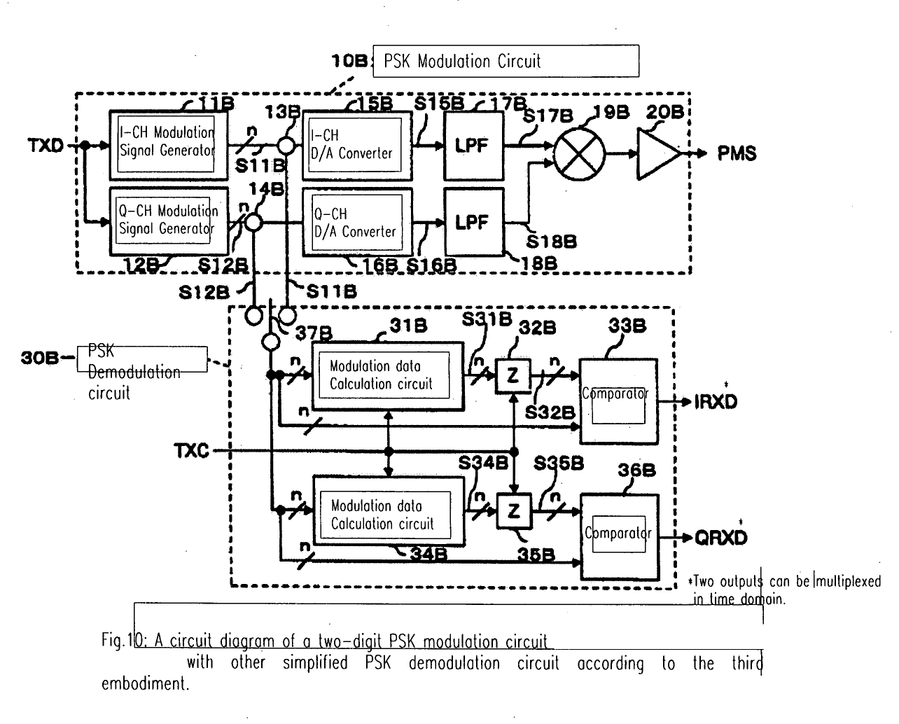

FIG. 10 is a circuit diagram describing a two-digit PSK modulation circuit including other simplified PSK modulation circuit according to the third embodiment. The element identical to the element in FIG. 8 is provided the same numerals.

The PSK modulation 30B-1 in FIG. 10 is changed to one of the I-CH side and the Q-CH side selected by the selecting device 13B, 14B is switched by the switching device 37B and connected thereto. The switching device 37B consists of a switching element switched by control signal, etc. Even when the before mentioned switching device 37B is added thereto, the mostly same effect as in FIG. 8 can be achieved.

### Fourth Embodiment

The present invention is not limited ti the above mentioned first, second, and third embodiment, and various modifications are possible. One of the modifications thereof is as the flowing (a), (b).

(a): The two-digit PSK modulation 10B and the simplified PSK modulation circuit 30B, 30B-1 connected thereto according to the third embodiment are explained as before, however, the same configuration as FIG. 8 or FIG. 10 can be applied to a four-digit PSK. In other words, when the I-CH input (S11B) and the I-CH modulation data (S32B) in the comparator 33B, 33B-1 of FIG. 8 or FIG. 10 are compared with each other, and when the Q-CH input (S12B) and the Q-CH demodulation data (S35B)in the comparator 36B, there is no change in the case of four-digit PSK, compared with the case of two-digit PSK. However, there is a simple difference that the same value is inputted to the I-CH/Q-CH in the case of two-digit PSK, while the different value is inputted thereto in the case of four-digit PSK due to the informarion per symbol twice as large as the two-digit PSK. Consequently, there is no influence to the configuration of the four-digit PSK.

(b): The simplified demodulation circuit 30,30-1,30A,30B,30B-1 according to the first, second, third, fourth embodiment can be applied to various uses, for example, LSI test, etc., by using digital data before D/A conversion in the FSK modulation circuit 10, 10a, or the PSK modulation circuit 10B, etc., having the function of generating the FSK modulation signal FMS or the PSK modulation signal PMS by inputting the I/Q signal after D/A conversion to the quadrature modulator 19, 19B. For the above applications, the modulation circuit 10, 10A, 10B and the demodulation circuit 30,30-1,30A,30A-1,30b,30B-1, can be changed to other configuration than the configurations shown in the drawings, responding to the application thereof.

This is a counterpart of and claims priority to Japanese patent application Serial Number 142982/2005, filed on May 16, 2005, the subject matter of which is incorporated herein by reference.

What is claimed is:

1. A demodulation circuit comprising a circuit configuration to conduct the demodulation thereof by inputting a plural of bits of I-channel modulation signal and Q-cannel modulation signal being generated from the sending data thereof; calculating in advance the value of said I-channel and said Q-channel in case where said same sending data continues after one symbol; and comparing said calculation value with said a plural of bits of I-channel modulation signal and Q-cannel modulation signal.

2. The demodulation circuit according to the claim 1, wherein said calculation circuit inputs said plural of bits of I-channel modulation signal and Q-cannel modulation signal and calculates the modulation signal at one symbol after without changing the phase thereof;
said delaying device delays said modulation signal at one symbol after by one symbol and outputs the delayed data thereof; and
said comparator compares said plural of bits of I-channel modulation signal and Q-cannel modulation signal with said delayed data and outputs the sending carrier.

3. A demodulation circuit comprising a circuit configuration to conduct the demodulation thereof by inputting the most significant sign bit from a plural of bits of I-channel modulation signal and the most significant sign bit from a plural of bits of Q-cannel modulation signal being generated from the sending data thereof; and by merely comparing said most significant sign bit from said plural of bits of I-channel modulation signal and said most significant sign bit from said plural of bits of Q-channel modulation signal at after one symbol in case where the ratio of the transmitting speed of said sending data and the modulation frequency deviation is two to one.

4. The modulation circuit according to the claim 3, wherein said delaying device inputs said most significant sign bit of said I-channel modulation signal and the most significant sign bit of said Q-cannel modulation signal; said comparator delays said sign bits by one symbol and outputs the delayed data thereof; and said comparator compares said most significant bit with said delayed data and outputs the modulation carrier.

5. A modulation method comprising;
modulating a sending data;
calculating a current modulation data of the modulated sending data in synchronization with a clock signal;
demodulating the modulated sending data by comparing the calculated current modulation data and a modulation data calculated by the clock signal at prior one symbol.
